(19) United States
(12) Patent Application Publication
(10) Pub. No.: US 2026/0223606 A1
(43) Pub. Date: Jul. 30, 2026

(54) SEMICONDUCTOR STRUCTURE AND METHOD FOR FORMING SEMICONDUCTOR STRUCTURE

(71) Applicant: Vanguard International Semiconductor Corporation, Hsinchu (TW)

(72) Inventors: Cheng-Wei CHOU, Taoyuan City (TW); Yu-Feng YAO, Taipei City (TW); Shyh-Chiang SHEN, Hsinchu City (TW)

(73) Assignee: Vanguard International Semiconductor Corporation, Hsinchu (TW)

(21) Appl. No.: 19/037,487

(22) Filed: Jan. 27, 2025

(51) Int. Cl. H01L 21/02; H01L 21/308

(52) U.S. Cl. CPC H10P 14/34; H10P 14/3238; H10P 50/691

(57) ABSTRACT

A semiconductor structure is provided. The semiconductor structure includes a substrate, a semiconductor layer disposed on the substrate, and a plurality of epitaxial stacks disposed the semiconductor layer. The substrate has a die region and a scribe region adjacent to each other. The epitaxial stacks are disposed on the substrate in the die region. There is an opening between each of the epitaxial stacks.

### BACKGROUND OF THE INVENTION

### Field of the Invention

The present invention relates to a semiconductor structure, and in particular to a semiconductor structure and a method for forming the same that may reduce stress accumulation.

### Description of the Related Art

In recent years, semiconductor structures have been used in various electronic products, such as high-power devices, computers, mobile phones, digital cameras and other electronic devices. Among these, gallium nitride (GaN-based) semiconductor materials are widely used in light emitting diode (LED) components, high frequency components and the like because they have many excellent material properties such as high thermal resistance, wide band-gap, high electron saturation rate, and the like.

Although the semiconductor structures produced in the prior art may generally meet their original intended uses, they still do not completely meet the requirements in all aspects. For example, when epitaxially growing semiconductor materials on current substrates, the mismatch between heat and material stress between the semiconductor material and the substrate may easily generate stress inside the semiconductor material, and this stress will accumulate as the thickness increases. When the critical value is exceeded, the stress will continue to be released and cause the substrate to deform, crack, or peel off the film. Therefore, developing a semiconductor structure that may further improve the performance and reliability is still one of the current research topics in the industry.

### BRIEF SUMMARY OF THE INVENTION

Embodiments of the present invention provide a semiconductor structure, including a substrate, a semiconductor layer disposed on the substrate, and a plurality of epitaxial stacks disposed on the substrate. The substrate includes a die region and a scribe region, which are adjacent to each other. The epitaxial stacks are disposed on the semiconductor layer in the die region. There is an opening between each of the epitaxial stacks.

In some embodiments, the substrate may be a 2-20 inch process carrier plate. The substrate may be a homogeneous substrate or a composite substrate. In some embodiments, the substrate has a thickness of 100-2000 micrometers (μm). In some embodiments, the semiconductor layer has a thickness of 0.1 nanometer (nm) to 2 micrometer (μm).

In some embodiments, the semiconductor layer is divided into a plurality of semiconductor sub-layers, and there are openings between the semiconductor sub-layers. The openings between the semiconductor sub-layers correspond to the openings between the epitaxial stacks.

In some embodiments, a side surface of the epitaxial stack are aligned with side surface of the semiconductor sub-layers. In other embodiments, a side surface of the epitaxial stacks protrude from a side surface of the semiconductor sub-layers. Specifically, the epitaxial stacks completely covers the side surface and the top surface of the semiconductor sub-layers. The epitaxial stacks also have a protrusion close to the substrate.

In some embodiments, the semiconductor structure further includes a patterned dielectric layer between the epitaxial stacks. The epitaxial stacks cover the side surface and a portion of the top surface of the patterned dielectric layer.

In some embodiments, the distance between the epitaxial stacks (the width of the openings) is greater than the height of the epitaxial stacks. That is, the opening is located in the scribe region and has an aspect ratio of 1:0.1-1:3000. In some embodiments, the opening is located in the scribe region and has a width of 20-100 micrometers (μm). This prevents the epitaxial stacks from connecting each other and reduces the wafer breakage rate. In some embodiments, the opening is located in the scribe region and serves as a scribe line.

In other embodiments, the opening may also be disposed in the die region and serve as a via hole. In this embodiment, the opening filled with conductive materials may be located between two semiconductor devices (such as high-electron mobility transistors (HEMTs)) to electrically connect the source electrode and the semiconductor layer.

Embodiments of the present invention provide a method for forming a semiconductor structure, including providing a substrate; forming a semiconductor layer on the substrate; forming a patterned photoresist layer on the semiconductor layer; patterning the semiconductor layer into a plurality of semiconductor sub-layers by using the patterned photoresist layer; forming a plurality of epitaxial stacks on the semiconductor sub-layers.

Embodiments of the present invention provide a method for forming a semiconductor structure, including providing a substrate; forming a semiconductor layer on the substrate; forming a dielectric layer on the semiconductor layer; forming a patterned photoresist layer on the dielectric layer; patterning the dielectric layer into a patterned dielectric layer by using the patterned photoresist; forming a plurality of epitaxial stacks on the semiconductor layer where the patterned dielectric layer is not formed.

### BRIEF DESCRIPTION OF THE DRAWINGS

The present disclosure can be more fully understood by reading the subsequent detailed description and examples with references made to the accompanying drawings, wherein:

FIG. 1 is a schematic cross-sectional view illustrating a substrate of a semiconductor structure according to some embodiments of the present invention.

FIGS. 2-4 are schematic cross-sectional views illustrating a semiconductor structure manufactured by method A at various stages according to some embodiments of the present invention.

FIG. 5 is a schematic cross-sectional view illustrating a semiconductor structure manufactured by method A according to other embodiments of the present invention.

FIGS. 6-9 are schematic cross-sectional views illustrating a semiconductor structure manufactured by method B at various stages according to some embodiments of the present invention.

FIG. 10 is a schematic cross-sectional view illustrating a semiconductor structure manufactured by method B according to other embodiments of the present invention.

FIGS. 11-12 are top views illustrating semiconductor structures according to some embodiments of the invention.

FIG. 13 is a schematic cross-sectional view illustrating a semiconductor structure according to other embodiments of the present invention.

### DETAILED DESCRIPTION OF THE INVENTION

The following disclosure provides many embodiments or examples for implementing different elements of the provided semiconductor devices. Specific examples of each component and its configuration are described below to simplify the description of the embodiments of the present invention. Of course, these are only examples and are not intended to limit the embodiments of the present invention. For example, if a description mentions that a first component is formed on a second component, it may include an embodiment in which the first and second components are in direct contact, or may include an additional component formed between the first and second components, so that they are not in direct contact. In addition, embodiments of the present invention may repeat reference numbers and/or letters in different examples. This repetition is for the sake of brevity and clarity and is not intended to indicate the relationship between the various embodiments discussed.

Furthermore, spatially related terms may be used in the following descriptions, such as “under”, “below”, “underneath”, “above”, “over” and other similar terms are used to simplify the description of the relationship between one element or component and other elements or other components as shown in the figures. Such spatially relative terms include, in addition to the directions depicted in the figures, various orientations of the device during use or operation. The device may be otherwise oriented (rotated 90 degrees or at other orientations) and the spatially relative descriptors used herein interpreted accordingly.

Some variations of the embodiments are described below. Similar reference numbers are used to identify similar components in the various figures and illustrated embodiments. It will be appreciated that additional steps may be provided before, during, and after the method, and some of the recited steps may be replaced or deleted for other embodiments of the method.

Here, the terms “about” and “approximately” usually mean within 20% of a given value or range, preferably within 10%, and more preferably within 5%. The quantities given here are approximate quantities, which means that without specific explanation, the meaning of “approximately” or “approximately” may still be implied.

Embodiments of the present invention provide a semiconductor structure, including a substrate, a semiconductor layer disposed on the substrate, and a plurality of epitaxial stacks disposed on the semiconductor layer. The substrate includes a die region and a scribe region adjacent to each other. The epitaxial stacks are disposed on the substrate in the die region. There is an opening between each of the epitaxial stacks.

By arranging openings between the epitaxial stacks, embodiments of the present invention may reduce the wafer breakage rate, and may also reduce the stress that the epitaxial stacks exert on the substrate. In particular, when the epitaxial stacks are formed through an epitaxial growth, the stress between the epitaxial film layers may be reduced, and the mechanical stress specification of the substrate may be made more generous. This reduces cracking or peeling of the film layers and reduces the wafer scrap rate. In addition, embodiments of the present invention achieve better process stability by using the QST substrate, which is a high-strength substrate and may resist large stress. Moreover, by patterning the semiconductor layer or providing a patterned dielectric layer, it helps to form a better etching profile and a higher wafer per hour (WPH), thereby improving mass production efficiency.

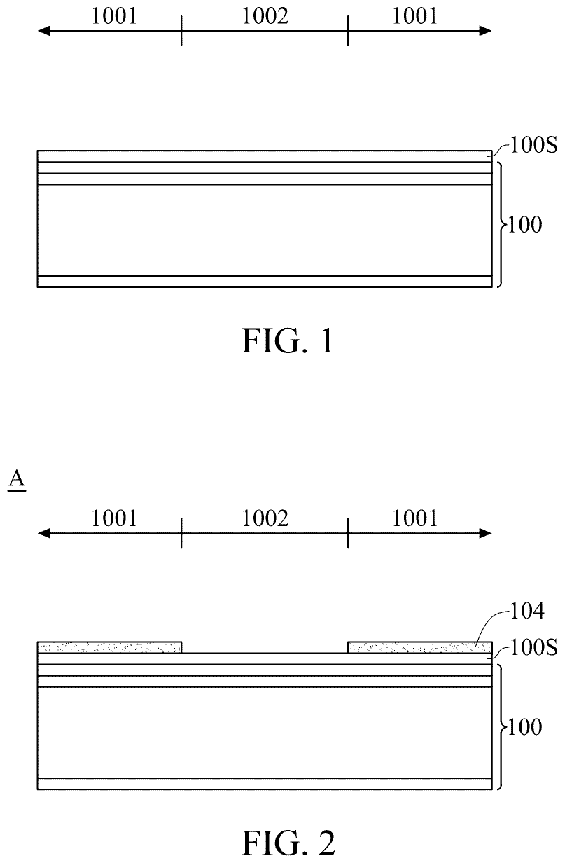

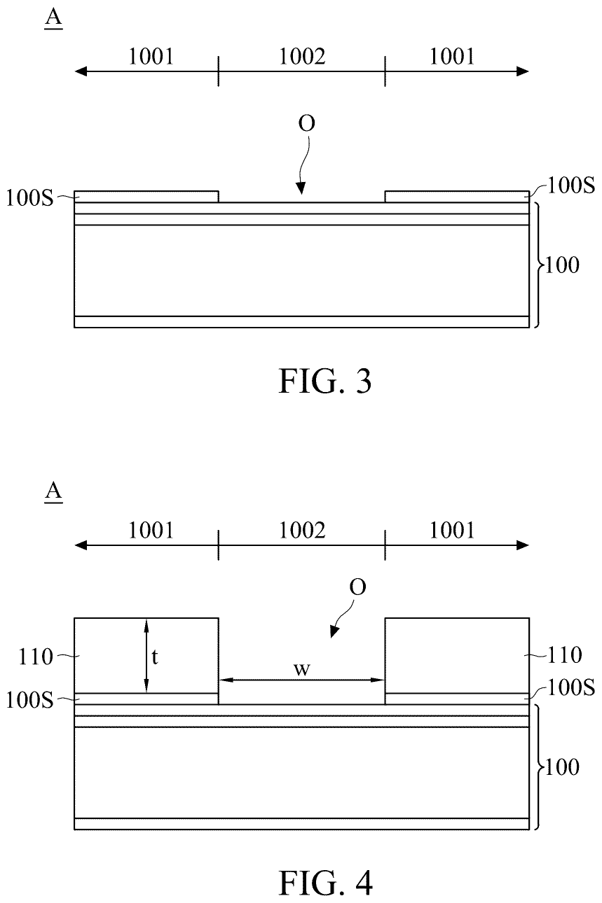

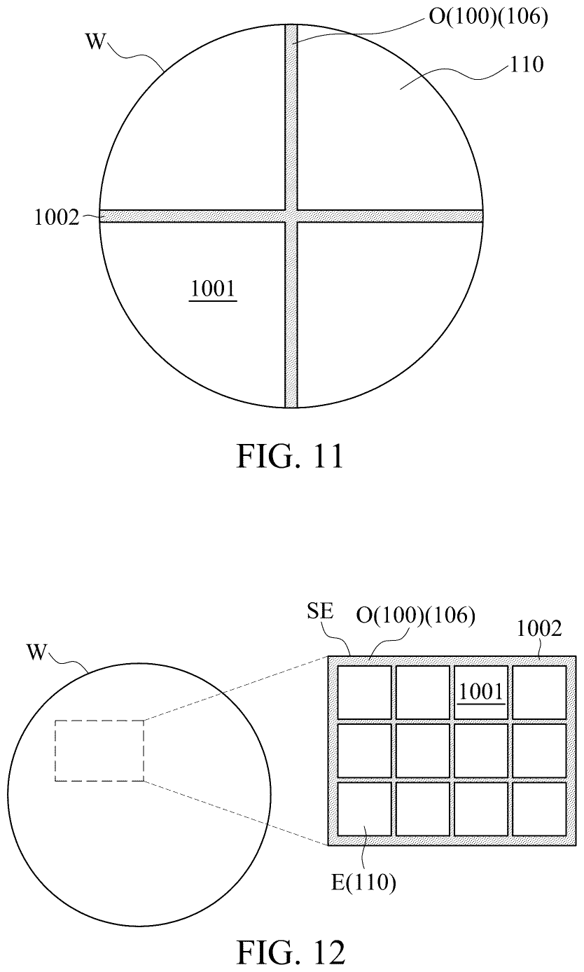

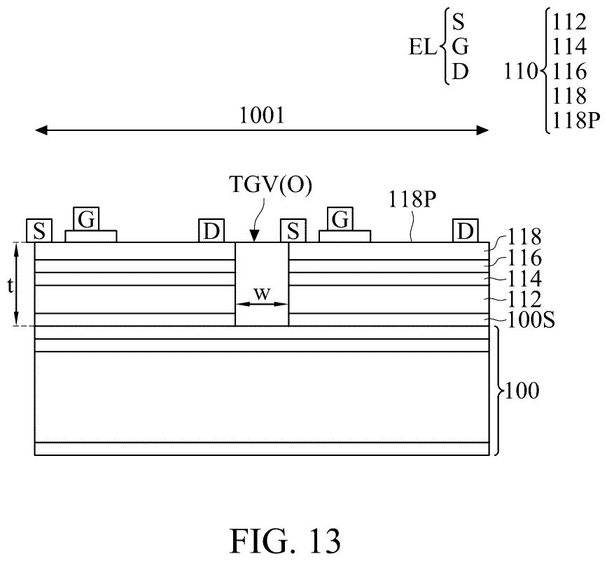

Below, the present invention will be described in detail through specific embodiments. FIG. 1 is a schematic cross-sectional view illustrating the substrate and the semiconductor layer in this embodiment. FIGS. 2-5 and 6-10 are schematic cross-sectional views illustrating semiconductor structures manufactured by the method A and the method B, respectively. FIGS. 11-12 are top views illustrating the application of semiconductor structures. FIG. 13 is a schematic cross-sectional view illustrating the application of semiconductor structures.

First, as shown in FIG. 1, a substrate 100 is provided. In some embodiments, the substrate 100 may be a process carrier plate with various sizes, such as a 2-20 inch process carrier plate. However, those skilled in the art may adjust the size and process carrier plate type according to actual needs. In some embodiments, the substrate 100 may be a homogeneous substrate or a composite substrate. For example, the substrate 100 may be a base material including a single material, a composite material, or a multi-layer film. In some embodiments, the homogeneous substrate may be a silicon substrate, a sapphire substrate, a ceramic substrate, or the like. In some embodiments, the composite substrate may be a QST substrate, silicon on insulator (SOI), or the like. The QST substrate refers to the substrate produced by Qromis Technology, Inc. in the United States. For example, it contains composite materials such as ceramic materials and insulating materials. In the embodiment of the present invention, the QST substrate of the composite substrate is used as an example for explanation, but the present invention is not limited thereto. In some embodiments, substrate 100 has a thickness of 100-2000 micrometers (μm).

As shown in FIG. 1, a semiconductor layer 100S is formed on the substrate 100. In some embodiments, the semiconductor layer 100S may have a single layer or multiple layers of semiconductor materials, such as silicon (Si), aluminum nitride (AlN), gallium nitride (GaN), aluminum gallium nitride (AlGaN), silicon carbide (SiC), other suitable materials or a combination of the above. In the embodiment of the present invention, the semiconductor layer 100S is silicon (1,1,1) of 0.1 nanometer (nm) to 2 micrometer (μm). This helps to change the pattern of the semiconductor layer, thereby reducing stress accumulation in subsequently grown epitaxial stacks. In some embodiments, the semiconductor layer 100S may be formed by a thin film transfer process, a wafer bonding process, or other suitable methods, such as the transfer from Si wafer provided by Qromis.

As shown in FIG. 1, the substrate 100 includes a die region 1001 and a scribe region 1002 adjacent to each other. In some embodiments, the scribe region 1002 may surround the die area 1001 (refer to FIG. 12). In some embodiments, die region 1001 may include dies, which may include various semiconductor devices, such as high electron mobility transistors (HEMTs) and the like. In some embodiments, the scribe region 1002 is used as a scribe line to separate the die (die region), and a cutting machine (cutter) or the like may be further used to scribe the substrate into individual die.

The following FIGS. 2-10 will illustrate the manufacturing process of the semiconductor structure of the method A and the method B based on FIG. 1.

First, the method A of manufacturing a semiconductor structure is explained with reference to FIGS. 2-4. As shown in FIG. 2, a patterned photoresist layer 104 is formed on the substrate 100. Specifically, the patterned photoresist layer 104 is located on the semiconductor layer 100S in the die region 1001. In some embodiments, the formation of the patterned photoresist layer 104 may include a photolithography process, which includes photoresist coating (for example, spin coating), soft baking, mask alignment, exposure, post-exposure baking, photoresist development, cleaning and drying (for example, hard baking), other suitable processes, a combination of the above or the like.

Next, as shown in FIG. 3, the patterned photoresist layer 104 is used to pattern the semiconductor layer 100S into a plurality of semiconductor sub-layers 100S. It should be noted that these semiconductor sub-layers 100S are located in the die region 1001, and the opening O located in the scribe region 1002 is formed between them. In some embodiments, the patterning of the semiconductor layer 100S may include a photolithography process and an etching process. The photolithography process is similar to the above and will not be described in detail here. The etching process may include a dry etching process, a wet etching process, or other suitable etching processes. For example, plasma etching, plasma-less gas etching, sputter etching, ion milling, reactive ion etching (RIE), neutral beam etching (NBE), inductive coupled plasma etching. The etching process may also be purely chemical etching, purely physical etching, or any combination thereof.

Next, as shown in FIG. 4, a plurality of epitaxial stacks 110 are formed on these semiconductor sub-layers 100S. In some embodiments, each epitaxial stack 110 may include a single layer and/or multiple layers of epitaxial materials. It should be noted that the semiconductor sub-layers 100S are located in the die region 1001, and therefore the formed epitaxial stacks 110 are also located in the die region 1001. The opening O located in the scribe region 1002 also separates the epitaxial stacks 110.

In some embodiments, the epitaxial stacks 110 may include epitaxial materials, which may be a III-V group semiconductor material, such as aluminum gallium nitride (AlGaN), gallium nitride (GaN), aluminum nitride (AlN), gallium arsenide (GaAs), gallium indium phosphide (GaInP), aluminum gallium arsenide (AlGaAs), indium phosphide (InP), indium aluminum arsenide (InAlAs), indium gallium arsenide (InGaAs), indium gallium nitride (InGaN), indium aluminum gallium nitride (InAlGaN), other suitable materials or a combination of the above. In embodiments of the present invention, III-V group semiconductor materials are used as examples. It should be noted that when III-V semiconductor materials are used in high-temperature and high-pressure environments, it is easy to cause serious deformation of the substrate. In this regard, compared to the conventional formation of III-V group semiconductor material on the entire surface of the substrate, in this embodiment, the III-V group semiconductor material is selectively formed on the substrate (or the III-V group semiconductor material is formed on a part of the substrate) to improve the problem that the substrate is easily deformed or broken.

In some embodiments, the formation of the epitaxial stacks 110 includes a selective epitaxial growth (selective area growth, SAG) process, a chemical vapor deposition (chemical vapor deposition, CVD) process, and a molecular beam epitaxial process (molecular beam epitaxy, MBE), depositing a doped amorphous semiconductor (for example, Si) followed by a solid-phase epitaxial recrystallization (SPER) step, direct transfer of seed crystals, or other suitable methods process. Chemical vapor deposition processes (CVD) include, for example, vapor-phase epitaxy (VPE) process, low pressure chemical vapor deposition (LPCVD) process, ultra-high vacuum chemical vapor deposition (UHV-CVD) process, or other suitable processes.

As shown in FIG. 4, the side surface of the epitaxial stacks 110 is aligned with the side surface of the semiconductor sub-layers 100S, but the present invention is not limited thereto. In some embodiments, the distance w between the epitaxial stacks 110 (or the width of the opening O) is greater than the height t of the epitaxial stack 110 (w>t), but the present invention is not limited thereto. This ensures that the epitaxial stacks are not connected and reduces stress accumulation caused by epitaxial growth, and thus reduces the wafer breakage rate. In some embodiments, the width w of the opening O is 20-100 micrometers (μm), but the present invention is not limited thereto. In some embodiments, the aspect ratio of the opening O is greater than 1:0.1 and less than 1:3000. It should be noted that since the height of the epitaxial stack (10-1000μm) is very large relative to the thickness of the semiconductor layer 100S (0.1 nm-2 μm), the aspect ratio of the opening O may be roughly regarded as the height t:width w. It should be noted that the opening O in the scribe region 1002 is on the order of micron-scale and has a small aspect ratio. In comparison, generally the opening O (used as a via hole) in the die region 1001 is nanoscale and has a larger aspect ratio.

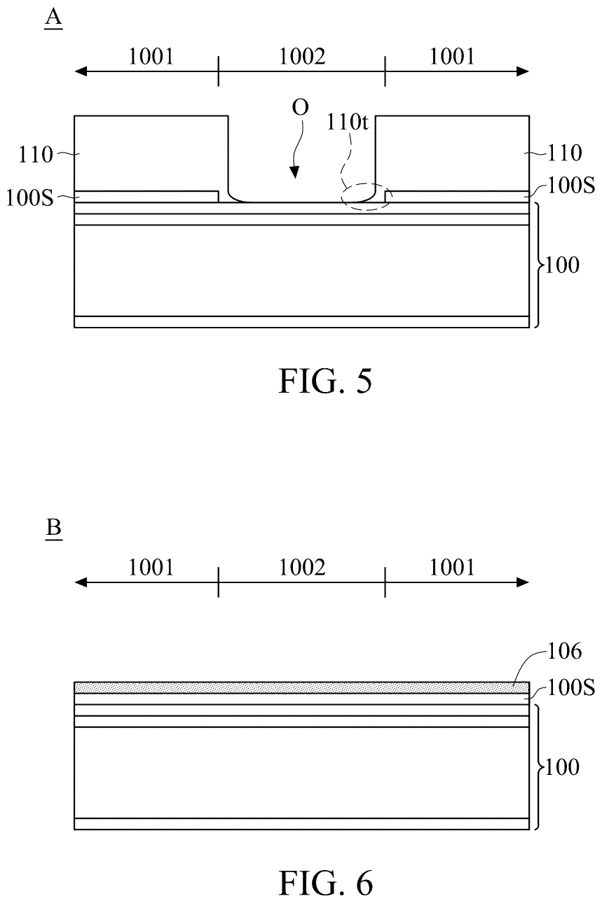

FIG. 5 shows another embodiment of a semiconductor structure manufactured by the method A. FIG. 5 is similar to FIG. 4 and the difference is that in FIG. 5, the epitaxial stack 110 is further formed in the scribe region 1002. Specifically, the epitaxial stack 110 protrudes from the side surface of the semiconductor sub-layer 100S, but the invention is not limited thereto. That is, the epitaxial stacks 110 extend and cover the side surface of the semiconductor sub-layers 100S. In addition, the epitaxial stacks 110 form a protrusion 110t close to the substrate 100 and the semiconductor sub-layers 100S, but the present invention is not limited thereto. It should be noted that although the protrusions 110t are formed on both sides of the opening O, the two protrusions are not connected (for example, the epitaxial stacks 110 are not connected to each other).

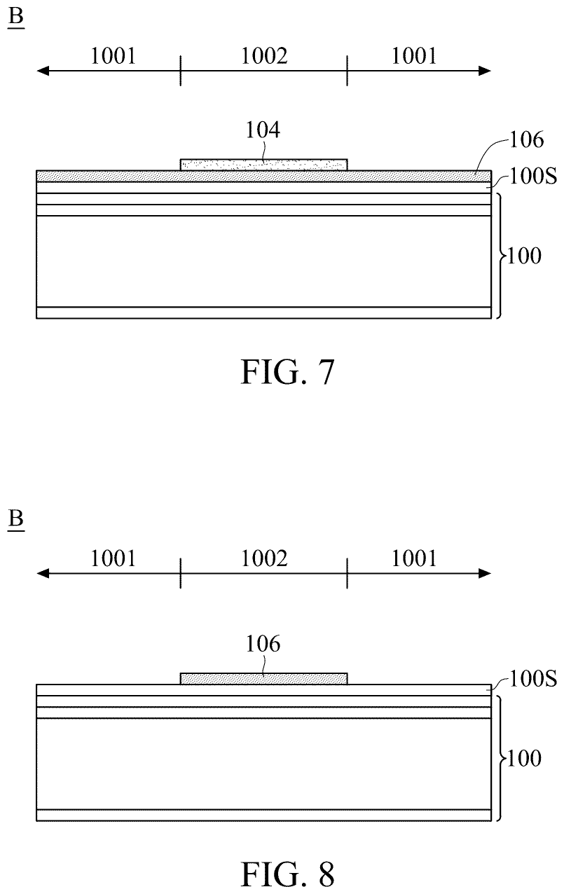

The method B of manufacturing a semiconductor structure is explained with reference to FIGS. 6-9. As shown in FIG. 6, a dielectric layer 106 is formed on the semiconductor layer 100S. In some embodiments, the dielectric layer 106 may have a thickness from several angstroms (Å) to several micrometers (μm), but the present invention is not limited thereto. In some embodiments, the dielectric layer 106 may include a dielectric material, such as an oxide. The aforementioned oxide may include silicon oxide, zirconium oxide, aluminum oxide, other suitable dielectric materials, or a combination of the foregoing. In some embodiments, the formation of the dielectric layer 106 may include a deposition process, which may include a chemical vapor deposition process, a physical vapor deposition process, an atomic layer deposition process, or a high-density plasma chemical vapor deposition (HDP-CVD) process, a combination of the above or the like.

Next, as shown in FIG. 7, a patterned photoresist layer 104 is formed on the dielectric layer 106 in the scribe region 1002. The formation of the patterned photoresist layer 104 is similar to the above and will not be described again.

Next, as shown in FIG. 8, the patterned photoresist layer 104 is used to pattern the dielectric layer 106 into the patterned dielectric layer 106. The patterned dielectric layer 106 is located in the scribe region 1002. The patterning of the dielectric layer 106 is similar to the above and will not be described again.

As shown in FIG. 9, a plurality of epitaxial stacks 110 are formed on the semiconductor layer 100S where the patterned dielectric layer 106 is not formed, and the opening O is formed on the patterned dielectric layer 106. That is, the epitaxial stacks 110 are formed on the semiconductor layer 100S which does not cover the patterned dielectric layer 106, and the opening O separates the epitaxial stacks 110. In some embodiments, the formation of the epitaxial stack 110 is similar to that described above and will not be described again.

As shown in FIG. 9, the patterned dielectric layer 106 and the opening O in the scribe region 1002 are disposed between the epitaxial stacks 110. In some embodiments, the side surface of the epitaxial stacks 110 is aligned with the side surface of the patterned dielectric layer 106. In some embodiments, the distance w between the epitaxial stacks 110 (or the width of the patterned dielectric layer 106) is also greater than the height t of the epitaxial stacks 110 (w>t), thereby ensuring that the distance between the epitaxial stacks 110 is not connected and reducing the accumulation of stress caused by epitaxial growth, and thus reducing the wafer breakage rate. Since the height of the epitaxial stack (10-1000μm) is very large relative to the thickness of the patterned dielectric layer 106 (several angstroms (Å) to several micrometers (μm)), the aspect ratio of the opening O may be roughly regarded as the height t:width w. The width w and aspect ratio of the opening O are similar to those described above and will not be described again here.

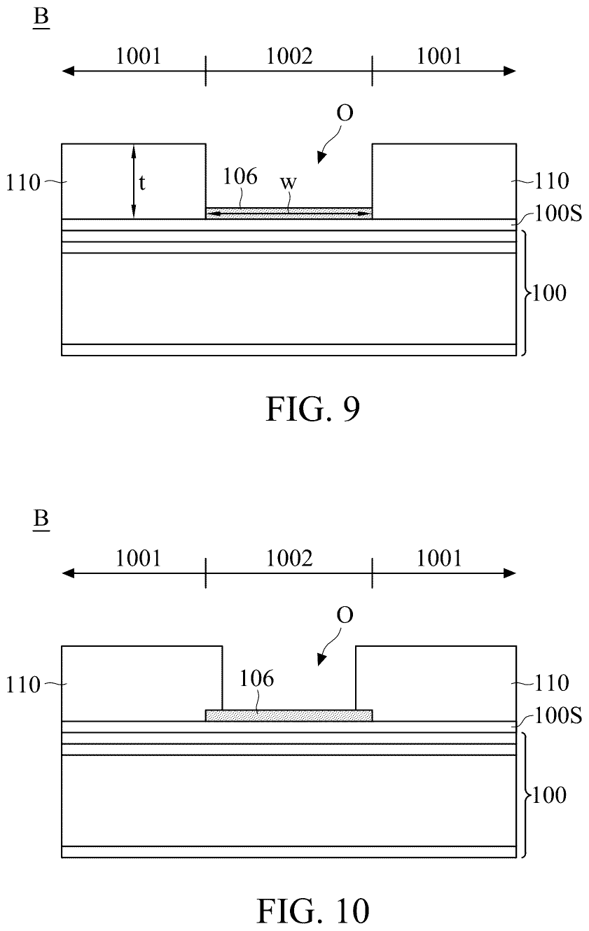

FIG. 10 shows another embodiment of a semiconductor structure manufactured by the method B. FIG. 10 is similar to FIG. 9 and the difference is that in FIG. 10, the epitaxial stacks 110 are further formed in the scribe region 1002. Specifically, the epitaxial stacks 110 cover the side surface and a portion of the top surface of the patterned dielectric layer 106, but the invention is not limited thereto. It should be noted that although the epitaxial stacks 110 extend into the scribe region 1002, they are not connected to each other.

Compared with directly forming the entire epitaxial stack from the substrate, in embodiments of the present invention, the epitaxial stacks are selectively formed (that is, the epitaxial stacks are spaced apart from each other or have openings between them), which may reduce the stress between the epitaxial film layers, reduce cracking or peeling of the film layers, and reduce the wafer scrap rate.

Next, a top view of the above-mentioned semiconductor structure is explained with reference to FIGS. 11-12. FIG. 11 shows an embodiment in which the substrate 100 is a wafer W. As shown in FIG. 11, a cross-shaped scribe region 1002 and a die area 1001 are divided on the wafer W. The opening O is exposed in the scribe region 1002, which exposes the substrate 100 (the method A) or the patterned dielectric layer 106 (the method B). The epitaxial stacks 110 are exposed in die region 1001.

FIG. 12 is an example of an enlarged view of any mask frame SE of the wafer W. As shown in FIG. 12, the mask frame SE includes a plurality of dies E in the die region 1001. The scribe region 1002 surrounds these dies E. These dies E may be epitaxial stacks 110. These epitaxial stacks 110 may be various semiconductor devices, such as high electron mobility transistors (HEMTs). Similarly, an opening O is also exposed in the scribe region 1002, and the opening O exposes the substrate 100 (the method A) or the patterned dielectric layer 106 (the method B).

Next, a schematic cross-sectional view of another embodiment using the above semiconductor structure is illustrated in FIG. 13. Specifically, the opening O is disposed in the die region 1001 and serves as a via hole.

As shown in FIG. 13, the epitaxial stacks 110 are formed on the semiconductor sub-layers 100S (the method A) and a semiconductor electrode EL is formed on the epitaxial stacks 110. Specifically, the epitaxial stacks 110 and the semiconductor electrode EL may be regarded as one semiconductor device. Therefore, the opening O in the die region 1001 may serve as an opening between two semiconductor devices. When a conductive material is filled in the opening O, the opening O may be used as a via hole TGV for grounding the substrate.

Since the aspect ratio of the via hole in the die region is large (for example, the opening is deeper), it is more difficult to etch to the desired depth after forming the predetermined epitaxial stack. In contrast, by selectively forming epitaxial stacks on the substrate in embodiments of the present invention, etching difficulty may be reduced and wafer per hour (WPH) may be increased, thereby improving mass production efficiency.

The following uses a high electron mobility transistor (HEMT) as an example of the epitaxial stacks 110 for illustration. Those with ordinary skill in the technical field of the present invention may also replace different semiconductor devices according to actual needs.

As shown in FIG. 13, the epitaxial stack 110 may include a buffer layer 112, a channel layer 116 and a barrier layer 118. The buffer layer 112 may alleviate the deformation (strain) caused by the stress caused by the channel layer subsequently formed above the buffer layer. A heterogeneous interface may be formed between the channel layer 116 and the barrier layer 118, and a two-dimensional electron gas (2DEG) (not shown) is formed on the heterogeneous interface due to the energy gap difference.

In some embodiments, the buffer layer 112, the channel layer 116 and the barrier layer 118 may include III-V group semiconductor materials, such as AlGaN, AIN, GaAs, GaInP, AlGaAs, InP, InAlAs, InGaAs, other appropriate III-V group materials or a combination of the above. Moreover, it may be formed by molecular beam epitaxy, organic metal chemical vapor deposition, hydride vapor epitaxy, other appropriate methods or a combination of the above methods.

As shown in FIG. 13, the epitaxial stack 110 may further include a first doped compound semiconductor layer 114 and a second doped compound semiconductor layer 118P. The first doped compound semiconductor layer 114 may serve as an electrical buffer layer and increase the breakdown voltage of the semiconductor structure. The second doped compound semiconductor layer 118P may serve as a switch for the semiconductor device.

In some embodiments, the first doped compound semiconductor layer 114 may be a carbon-doped layer between the buffer layer 112 and the channel layer 116, such as carbon-containing gallium nitride (C—GaN) layer. In some embodiments, the second doped compound semiconductor layer 118P may be P-type doped gallium nitride formed on the barrier layer 118.

In some embodiments, the first doped compound semiconductor layer 114 and the second doped compound semiconductor layer 118P may be formed by atomic layer deposition, chemical vapor deposition, physical vapor deposition, epitaxial process, ion implantation or in-situ doping process.

As shown in FIG. 13, the semiconductor electrode EL may be formed on the epitaxial stack 110. The semiconductor electrode EL may include a gate electrode G, and a source electrode S and a drain electrode D disposed on both sides of the gate electrode G. The source electrode S may be connected to the substrate 100 (ground) through the via hole TGV.

In some embodiments, the gate electrode G, the source electrode S, and the drain electrode D may include metal materials, metal silicides, polycrystalline silicon, other appropriate conductive materials, or combinations thereof. Examples include gold (Au), nickel (Ni), platinum (Pt), palladium (Pd), iridium (Ir), titanium (Ti), chromium (Cr), tungsten (W), aluminum (Al), copper (Cu), tantalum nitride (TaN), titanium nitride (TiN), tungsten silicide (WSi₂), a combination of the above, or a similar material. In some embodiments, it may be formed by atomic layer deposition, chemical vapor deposition, physical vapor deposition (such as sputtering), or a similar process.

Based on the above, by forming the openings O between the semiconductor devices in the die region 1001, it is easier to form via holes to a predetermined depth, thereby increasing the performance of the semiconductor devices.

In addition, compared with a conventional silicon substrate, by using a QST substrate as the substrate 100 and forming the opening O, it is easier to ground the via hole, thereby reducing semiconductor manufacturing costs.

In summary, embodiments of the present invention may reduce the stress that the epitaxial stack exerts on the substrate by selectively forming the epitaxial stacks. In particular, the stress on the epitaxial stack itself may be reduced, and cracking or peeling between film layers may be reduced. The openings between the epitaxial stacks may be located in the scribe region and serve as the scribe line to facilitate subsequent scribing operations. The openings between the epitaxial stacks may be also located in the die region and have a better etching profile, which facilitates the formation of via holes of a predetermined depth.

Although the embodiments and advantages of the present disclosure have been disclosed above, it should be understood that anyone with ordinary knowledge in the art may make changes, substitutions and modification without departing from the spirit and scope of the disclosure. In addition, the protection scope of the present disclosure is not limited to the processes, machines, manufacturing, material compositions, devices, methods and steps in the specific embodiments described in the specification. Anyone with ordinary knowledge in the relevant technical field may learn from some implementations of the present disclosure. It is understood that processes, machines, manufacturing, material compositions, devices, methods and steps currently or developed in the future may be based on the disclosure of the examples as long as they may perform substantially the same functions or obtain substantially the same results in the some embodiments of the present disclosure described herein. Therefore, the protection scope of the present disclosure includes the above-mentioned processes, machines, manufacturing, material compositions, devices, methods and steps. In addition, each claimed patent scope constitutes an individual embodiment, and the protection scope of the present disclosure also includes the combination of each claimed patent scope and embodiments.

What is claimed is:

1. A semiconductor structure, comprising:
a substrate having a die region and a scribe region adjacent to each other;
a semiconductor layer disposed on the substrate; and
a plurality of epitaxial stacks disposed on the substrate in the die region,
wherein there is an opening between each of epitaxial stacks.

2. The semiconductor structure as claimed in claim 1, wherein a distance between the epitaxial stacks is greater than the height of any one of the epitaxial stacks.

3. The semiconductor structure as claimed in claim 1, wherein the semiconductor layer is divided into a plurality of semiconductor sub-layers, wherein the openings are disposed between the semiconductor sub-layers.

4. The semiconductor structure as claimed in claim 3, wherein a side surface of any one of the epitaxial stacks is aligned with a side surface of a corresponding of the semiconductor sub-layers.

5. The semiconductor device as claimed in claim 3, wherein any one of the epitaxial stacks protrudes from a side surface of a corresponding of the semiconductor sub-layers.

6. The semiconductor structure as claimed in claim 3, wherein any one of the epitaxial stacks covers a side surface and a top surface of any one of the semiconductor sub-layers.

7. The semiconductor structure as claimed in claim 6, wherein each one of the epitaxial stacks has a protrusion close to the substrate.

8. The semiconductor structure as claimed in claim 1, further comprising: a patterned dielectric layer disposed between the epitaxial stacks.

9. The semiconductor structure as claimed in claim 8, wherein any one of the epitaxial stacks covers a side surface and a portion of a top surface of the patterned dielectric layer.

10. The semiconductor structure as claimed in claim 1, wherein the semiconductor layer comprises silicon (1,1,1).

11. The semiconductor structure as claimed in claim 1, wherein the substrate is a 2-20 inch process carrier plate.

12. The semiconductor structure as claimed in claim 1, wherein the opening is located in the scribe region and serves as a scribe line.

13. The semiconductor structure as claimed in claim 1, wherein the opening is located in the scribe line and has a width of 20-100 micrometers (μm).

14. The semiconductor structure as claimed in claim 1, wherein the opening is located in the scribe line and has an aspect ratio of 1:0.1-1:3000.

15. The semiconductor structure as claimed in claim 1, wherein the substrate has a thickness of 100-2000 micrometers (μm).

16. The semiconductor structure as claimed in claim 1, wherein the semiconductor layer has a thickness of 0.1 nanometers (nm)-2 micrometers (μm).

17. The semiconductor structure as claimed in claim 1, wherein the opening is located in the die region and serves as a via hole.

18. A method for forming a semiconductor structure, comprising:
providing a substrate, wherein the substrate has a die region and a scribe region adjacent to each other;
forming a semiconductor layer on the substrate; and
forming a plurality of epitaxial stacks separated from each other disposed on the substrate in the die region.

19. The method as claimed in claim 18, further comprising:
forming a patterned photoresist layer on the semiconductor layer in the die region; and
patterning the semiconductor layer into a plurality of semiconductor sub-layers by using the patterned photoresist layer,
wherein forming the plurality of epitaxial stacks separated from each other comprises:
forming the plurality of epitaxial stacks on the plurality of semiconductor sub-layers.

20. The method as claimed in claim 18, further comprising:
forming a dielectric layer on the semiconductor layer;
forming a patterned photoresist layer on the dielectric layer in the scribe region; and
patterning the dielectric layer into a patterned dielectric layer by using the patterned photoresist layer, wherein the patterned dielectric layer is located in the scribe region,
wherein forming the plurality of epitaxial stacks separated from each other comprises:
forming the plurality of epitaxial stacks on the semiconductor layer where the patterned dielectric layer is not formed.
